(19) United States
(12) Patent Application Publication
(10) Pub. No.: US 2024/0172533 A1
(43) Pub. Date: May 23, 2024

(54) DISPLAY DEVICE AND METHOD FOR MANUFACTURING THE SAME

(71) Applicant: Samsung Display Co., Ltd., Yongin-si (KR)

(72) Inventors: Jongchan Lee, Yongin-si (KR); Yongho Yang, Yongin-si (KR); Jinsuk Lee, Yongin-si (KR); Seunggyu Tae, Yongin-si (KR)

(73) Assignee: Samsung Display Co., Ltd., Yongin-si (KR)

(21) Appl. No.: 18/499,264

(22) Filed: Nov. 1, 2023

(30) Foreign Application Priority Data
Nov. 22, 2022 (KR) 10-2022-0157503
Aug. 10, 2023 (KR) 10-2023-0105089

(51) Int. Cl. H10K 59/80; H10K 59/12; H10K 59/124

(52) U.S. Cl. CPC H10K 59/873; H10K 59/1201; H10K 59/124

(57) ABSTRACT

A display device may include a substrate including an opening area, a display area surrounding at least a portion of the opening area, and an intermediate area disposed between the opening area and the display area; an inorganic insulating layer disposed on the substrate and including holes disposed therein; a first organic insulating layer filling the holes and having grooves disposed in a top surface thereof; a metal layer disposed on the first organic insulating layer and comprising end portions; and a protective layer disposed on the metal layer, wherein each of the end portions of the metal layer are spaced apart from one another above at locations corresponding to the grooves in a plan view, and top surfaces and side surfaces of each of the end portions of the metal layer in a plan view are covered by the protective layer.

### CROSS-REFERENCE TO RELATED APPLICATIONS

This application claims priority under 35 U.S.C.§ 119 from Korean Patent Application No. 10-2022-0157503 filed on Nov. 22, 2022 and from Korean Patent Application No. 10-2023-0105089 filed on Aug. 10, 2023 in the Korean Intellectual Property Office, the entire contents of which are incorporated herein by reference.

### BACKGROUND

### 1. Technical Field

The disclosure relates to a display device and a method of manufacturing the same.

### 2. Description of the Related Art

Recently, display devices have been used in various ways. Due to decreased thicknesses and light weight thereof, display devices tend to be more widely used.

In accordance with an increase in an area occupied by a display area in display devices, various functions added or linked to display devices are increasing. There have been studies on display devices in which various components in display areas may be disposed, as a solution to add various functions while expanding areas of display devices.

### SUMMARY

A display device having an opening area that may be used for various purposes may be provided. For example, various kinds of components may be disposed in a display area of the disclosure. However, this may be merely an example, and the scope of the disclosure may not be limited thereto.

Additional aspects will be set forth in part in the description which follows and, in part, will be apparent from the description, or may be learned by practice of the presented embodiments of the disclosure.

According to an aspect of the embodiments, a display device may include an opening area, a display area surrounding at least a portion of the opening area, and an intermediate area disposed between the opening area and the display area, an inorganic insulating layer disposed on a substrate and including a plurality of holes, a first organic insulating layer filling the plurality of holes and having a plurality of grooves disposed in a top surface, a metal layer disposed on the first organic insulating layer and including a plurality of end portions, and a protective layer disposed on the metal layer, wherein each of the plurality of end portions of the metal layer is spaced apart from one another, and top surfaces and side surfaces of each of the plurality of end portions of the metal layer are covered by the protective layer.

According to one or more embodiments, the protective layer may also be disposed at a location corresponding to the plurality of grooves disposed in the first organic insulating layer.

According to one or more embodiments, the display device may further include a first dam disposed in the intermediate area.

According to one or more embodiments, at least one of the plurality of holes defined in the inorganic insulating layer may be disposed between the display area and the first dam, and the first organic insulating layer filling the at least one of the plurality of holes disposed between the display area and the first dam may include at least one of the plurality of grooves disposed on a top surface.

According to one or more embodiments, the display device may further include a second dam disposed between the first dam and the opening area.

According to one or more embodiments, at least one of the plurality of holes defined in the inorganic insulating layer may be disposed between the first dam and the second dam, and the first organic insulating layer filling the at least one of the plurality of holes disposed between the first dam and the second dam may include at least one of the plurality of grooves disposed on the top surface.

According to one or more embodiments, each of the first dam and the second dam may include a second organic insulating layer; and a third organic insulating layer disposed on the second organic insulating layer.

According to one or more embodiments, at least one of the plurality of holes defined in the inorganic insulating layer may be disposed between the second dam and the opening area, and the first organic insulating layer filling the at least one of the plurality of holes disposed between the second dam and the opening area may include at least one of the plurality of grooves disposed on the top surface.

According to one or more embodiments, the display device may also include a light-emitting device that may include a pixel electrode and a counter electrode disposed in the display area and a functional layer disposed between the pixel electrode and the counter electrode, wherein the protective layer and the pixel electrode may include a same material.

According to one or more embodiments, in a portion of the intermediate area adjacent to the display area, the protective layer may cover side surfaces and a top surface of a peripheral end of the metal layer contacting the second organic insulating layer. According to one or more embodiments, the third organic insulating layer included in the first dam may cover the metal layer and the protective layer contacting the second organic insulating layer included in the first dam.

According to one or more embodiments, the third organic insulating layer included in the second dam may cover the metal layer and the protective layer contacting the second organic insulating layer included in the second dam.

According to another aspect, a method of manufacturing a display device may include forming an inorganic insulating layer on a substrate, the display device including an opening area, a display area surrounding at least a portion of the opening area, and an intermediate area disposed between the opening area and the display area, forming a plurality of holes by removing at least a portion of the inorganic insulating layer disposed in the intermediate area, forming a first organic insulating layer in the plurality of holes of the inorganic insulating layer, forming a metal layer on the first organic insulating layer, forming a plurality of end portions in the metal layer by etching at least a portion of the metal layer corresponding to the plurality of holes, and forming a protective layer on the metal layer, wherein the protective layer may cover top surfaces and side surfaces of each of the plurality of end portions of the metal layer.

According to one or more embodiments, in the forming of the plurality of end portions of the metal layer by etching the at least a portion of the metal layer corresponding to the plurality of holes, the at least a portion of the first organic insulating layer may be simultaneously etched to produce the plurality of grooves disposed in the first organic insulating layer.

According to one or more embodiments, the protective layer may also be disposed at a location corresponding to the plurality of grooves disposed in the first organic insulating layer.

According to one or more embodiments, ones of the plurality of end portions of the metal layer may be spaced apart from one another and are disposed at a location corresponding to the grooves.

According to one or more embodiments, the forming of the plurality of end portions in the metal layer by etching the at least a portion of the metal layer corresponding to the plurality of holes may include arranging a photoresist on the metal layer, patterning the photoresist by removing a portion of the photoresist disposed on the at least a portion of the metal layer corresponding to the plurality of holes, etching and removing the at least a portion of the metal layer corresponding to the holes, and removing the patterned photoresist.

According to one or more embodiments, the protective layer may be simultaneously formed with a pixel electrode of a light-emitting device disposed in the display area.

According to one or more embodiments, the protective layer and the pixel electrode may include a same material.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a perspective view schematically illustrating a display device according to an embodiment;

FIG. 2 is a schematic cross-sectional view illustrating a display device according to an embodiment;

FIG. 3 is a top-plan view schematically illustrating a display device according to an embodiment;

FIG. 4 is a schematic diagram of an equivalent circuit of any one pixel in a display device according to an embodiment;

FIG. 5 is a top-plan view schematically illustrating a portion of a display device according to an embodiment;

FIG. 6 is a schematic cross-sectional view of a display device according to an embodiment;

FIGS. 7A to 7C are schematic cross-sectional views illustrating a display device according to an embodiment;

FIG. 8A is an enlarged, schematic cross-sectional view of region ‘C’ of FIG. 7A;

FIG. 8B is an enlarged schematic cross-sectional view of a portion of FIG. 8A; and

FIGS. 9 to 15 are schematic cross-sectional views of a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

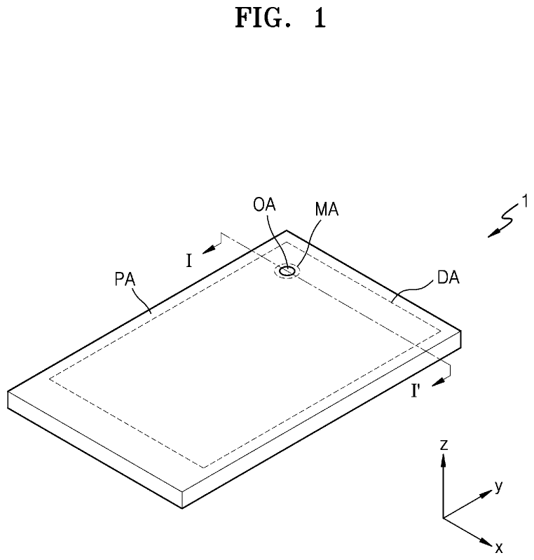

FIG. 1 is a perspective view schematically illustrating a display device 1 according to an embodiment. Referring to FIG. 1, the display device 1, as a device configured to display videos or still images, may be used as a display screen of various products such as televisions, laptop computers, monitors, billboard charts, Internet of things (IOT), as well as mobile electronic devices such as mobile phones, smart phones, tablet personal computers, mobile communication terminals, electronic notebooks, electronic books, portable multimedia players (PMP), navigation systems, and ultra mobile PCs (UMPC). The display device 1 according to an embodiment may be used for wearable devices such as smart watches, watch phones, and head mounted displays (HMD). The display device 1 according to an embodiment may be used as dashboards of vehicles, center fascia of vehicles, center information displays (CID) disposed on dashboards, room mirror displays for replacing side mirrors of vehicles, entertainment for passengers in rear seats of vehicles, or displays disposed on rear surfaces of front seats. The aforementioned electronic devices are bendable, foldable, or rollable. For convenience of explanation, FIG. 1 illustrates that the display device 1 according to an embodiment may be used as a smartphone.

In a plan view, the display device 1 may have a rectangular shape. For example, the display device 1 may have a rectangular plane shape having a short side in the x direction and a long side in the y direction, as shown in FIG. 1. A corner at which the short side in the x direction and the long side in the y direction meet each other may be formed in a round shape with a certain curvature or may be formed in a right angle. The plane shape of the display device 1 may not be limited to a rectangle, and may be formed into other polygons, ovals, or amorphous shapes.

The display device 1 may include an opening area OA and a display area DA at least partially surrounding the opening area OA. The display device 1 may include an intermediate area MA between the opening area OA and the display area DA, and a peripheral area PA surrounding a periphery of the display area DA. The intermediate area MA and the peripheral area PA may each correspond to a non-display area that does not emit light.

The opening area OA may be inside the display area DA. As an embodiment and as shown in FIG. 1, the opening area OA may be disposed in the middle of the top of the display area DA. Instead, the opening area OA may be disposed in various other positions, e.g., a center of the display area DA, left-top of the display area DA, or right-top of the display area DA. In the top-plan view of the specification, “left.” “right.” “up.” and “down” indicates a direction in case that the display device 1 is seen in a direction perpendicular to the display device 1 (i.e., in a plan view). For example, “left” indicates the −x direction, “right” indicates the +x direction, “up” indicates the +y direction, and “down” indicates the −y direction. Although FIGS. 1A and 1B illustrate that only one opening area OA may be disposed, as an embodiment, multiple opening areas OA may instead be provided.

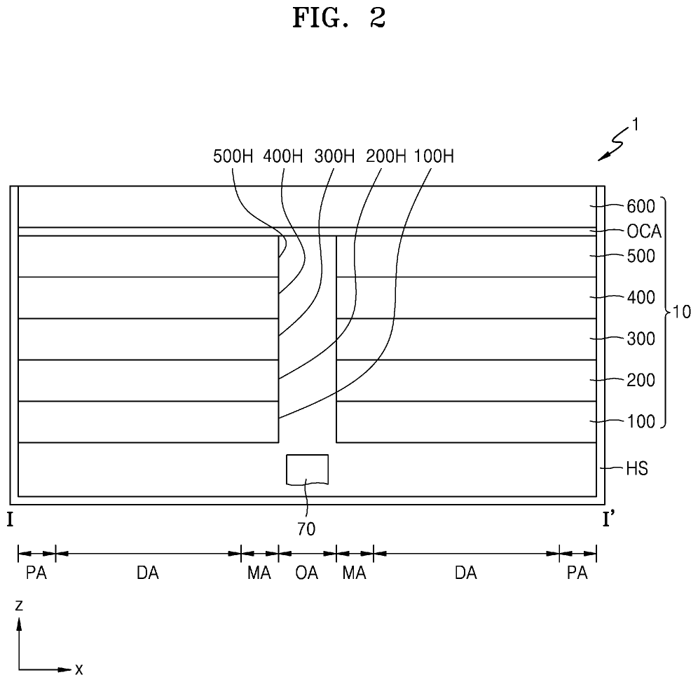

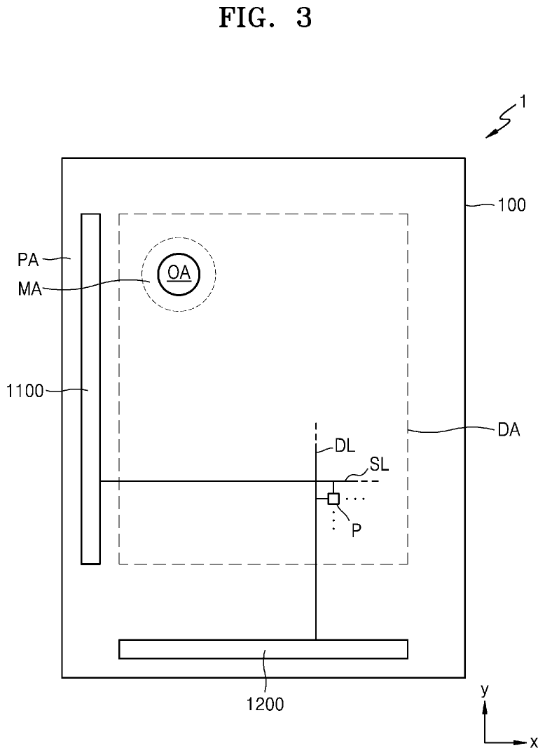

FIG. 2 is a schematic cross-sectional view of the display device 1 according to an embodiment. More particularly, FIG. 2 shows a schematic cross-section taken along line I-I′ shown in FIG. 1. Referring to FIG. 2, the display device 1 may include a display panel 10 and a component 70 disposed in the opening area OA of the display panel 10. The display panel 10 and the component 70 may be accommodated into a housing HS.

The display panel 10 may include a substrate 100, a display layer 200, an encapsulation layer 300, an input sensing layer 400, an optical function layer 500, and a cover window 600. The display layer 200 may include light-emitting elements (e.g., light-emitting diodes) configured to emit light to display images and circuit elements electrically connected to the light-emitting elements and including transistors.

The encapsulation layer 300 may encapsulate light-emitting elements of the display layer 200. As an embodiment, the encapsulation layer 300 may include an inorganic encapsulation layer and an organic encapsulation layer. As an embodiment, the encapsulation layer 300 may include a sealing substrate facing the substrate 100 included in the display panel 10 and including a material substantially identical to a material included in the substrate 100.

The input sensing layer 400 may obtain coordinate information according to external inputs, e.g., touch events. The input sensing layer 400 may include a sensing electrode (or a touch electrode) and a trace line electrically connected thereto. The input sensing layer 400 may be above the display layer 200. The input sensing layer 400 may sense external inputs in a mutual cap method and/or a self-cap method.

The input sensing layer 400 may be formed (e.g., directly formed) above the display layer 200, or may be separately formed and later bonded to the display layer 200 through an adhesive layer such an optical clear adhesive. For example, the input sensing layer 400 may be sequentially formed after a process of forming the display layer 200, and the adhesive layer may not be between the input sensing layer 400 and the display layer 200. Although FIG. 2 illustrates that the input sensing layer 400 may be between the display layer 200 and the optical functional layer 500, as an embodiment, the input sensing layer 400 may instead be on the optical functional layer 500.

The optical functional layer 500 may include a reflection prevention layer. The reflection prevention layer may reduce a reflectance of light (foreign light) incident to the display panel 10 from the outside through the cover window 600. The reflection prevention layer may include a retarder and a polarizer.

As an embodiment, the reflection prevention layer may include a black matrix and color filters. The color filters may be aligned considering colors of light emitted from each of the light-emitting diodes of the display layer 200. As an embodiment, the reflection prevention layer may include a destructive interference structure. The destructive interference structure may include a first reflective layer and a second reflective layer respectively disposed on different layers. First reflected light and second reflected light respectively reflected from the first reflective layer and the second reflective layer may undergo destructive interference, and accordingly, the reflectance of the foreign light may be reduced.

The optical functional layer 500 may include a lens layer. The lens layer may improve emission efficiency of light emitted from the display layer 200 or reduce color deviation of the light. The lens layer may include a layer having a lens shape that may be concave or convex, and/or multiple layers reflectively having different refractive indices. The optical functional layer 500 may include both of the reflection prevention layer and the lens layer described above, or may include any one thereof.

Any one selected from among the substrate 100, the display layer 200, the encapsulation layer 300, the input sensing layer 400, and the optical functional layer 500 may include a through hole. As an embodiment, FIG. 2 illustrates that the substrate 100, the display layer 200, the encapsulation layer 300, the input sensing layer 400, and the optical functional layer 500 respectively include first to fifth through holes (i.e., a first through hole 100H, a second through hole 200H, a third through hole 300H, a fourth through hole 400H, and a fifth through hole 500H). The first through hole 100H, second through hole 200H, third through hole 300H, fourth through hole 400H, and fifth through hole 500H may overlap one another in the opening area OA.

The first through hole 100H may penetrate a bottom surface of the substrate 100 from a top surface of the substrate 100, and the second through hole 200H may penetrate a bottom surface of the display layer 200 from a top surface of the display layer 200. The third through hole 300H may penetrate a bottom surface of the encapsulation layer 300 from a top surface of the encapsulation layer 300, and the fourth through hole 400H may penetrate a bottom surface of the input sensing layer 400 from a top surface of the input sensing layer 400. The fifth through hole 500H may be a through hole penetrating a bottom surface of the optical functional layer 500 from a top surface of the optical functional layer 500. The first to fifth through holes 100H, 200H, 300H, 400H, and 500H may be disposed in the opening area OA to overlap one another. The first to fifth through holes 100H, 200H, 300H, 400H, and 500H may have a same size or different sizes.

The cover window 600 may be above the optical functional layer 500. The cover window 600 may be bonded to the optical functional layer 500 through an adhesive layer such as an optical clear adhesive (OCA) between the cover window 600 and the optical functional layer 500. The cover window 600 may include glass material, plastic material, or a combination thereof. For example, the cover window 600 may include an ultra-thin glass window. For example, the cover window 600 may include polyether sulfone, polyacrylate, polyether imide, polyethylene naphthalate, polyethylene terephthalate, polyphenylene sulfide, polyarylate, polyimide, polycarbonate, cellulose acetate propionate, the like, or a combination thereof.

The opening area OA may include a kind of a component area (e.g., a sensor arca, a camera area, a speaker area, and the like) in which the component 70 may be configured to add various functions to the display device 1. The component 70 may be below the display panel 10 to overlap the first through hole 100H of the substrate 100. For example, the component 70 may be on a bottom surface of the substrate 100. The component 70 may include electronic elements. For example, the component 70 may include an electronic element using light or acoustics. For example, the electronic element may include a sensor using light, e.g., an infrared ray sensor, a camera configured to collect light and capture images, a sensor configured to measure distances or recognize fingerprints and the like by outputting and sensing light or acoustics, a small-size lamp configured to output light, a speaker configured to output sound, or the like. The electronic element using light may use light of various wavelength bands, for example, visible light, infrared light, ultraviolet light, and the like. Light and/or acoustics output from the component 70 to the outside or moving from the outside toward the component 70 may move through the opening area OA.

As an embodiment, in case that the display device 1 is used as a smart watch or a dashboard of a vehicle, the component may be used as a member including a watch hand or a needle indicating certain information (e.g., speed of a vehicle). For the component 70 such as the needle to be exposed to the outside, the cover window 600 may include an opening in the opening area OA, unlike shown in FIG. 2. For example, in case that the display device 1 includes the component 70 as a speaker, the cover window 600 may include an opening corresponding to the opening area OA.

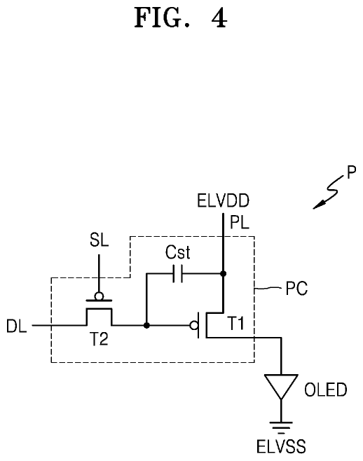

FIG. 3 is a top-plan view schematically illustrating the display device 1 according to an embodiment; and FIG. 4 is a schematic diagram of an equivalent diagram of any one pixel of the display device 1 according to an embodiment. Referring to FIG. 3, the display device 1 may include the opening area OA, the display area DA, the intermediate area MA, and the peripheral area PA. FIG. 3 may be understood as an image of the substrate 100 in the display device 1. For example, it may be understood that the substrate 100 has the opening area OA, the display area DA, the intermediate area MA, and the peripheral area PA.

The display device 1 includes multiple sub-pixels P disposed in the display area DA. As shown in FIG. 4, each of the sub-pixels P may include a pixel circuit PC and an organic light-emitting diode OLED as a display element electrically connected to the pixel circuit PC. The pixel circuit PC may include a first thin-film transistor T1, a second thin-film transistor T2, and a storage capacitor Cst. Each of the sub-pixels P may emit, for example, red, green, or blue light, or may emit red, green, blue, or white light through the organic light-emitting diode OLED.

The second thin-film transistor T2, which may be a switching thin-film transistor, may be electrically connected to a scan line SL and a data line DL, and may transmit a data voltage, which may be input from the data line DL, to the first thin-film transistor T1 based on a switching voltage input from the scan line SL. The storage capacitor Cst may be electrically connected to the second thin-film transistor T2 and a driving voltage line PL, and may store a voltage corresponding to a difference between the data voltage delivered from the second thin-film transistor T2 and a first power voltage ELVDD provided to the driving voltage line PL.

The first thin-film transistor T1, which may be a driving thin-film transistor, may be electrically connected to the driving voltage line PL and the storage capacitor Cst, and may control a driving current flowing through the organic light-emitting diode OLED from the driving voltage line PL in response to a value of the voltage stored in the storage capacitor Cst. The organic light-emitting diode OLED may emit light having a certain luminance according to the driving current. A counter electrode (for example, a cathode) of the organic light-emitting diode OLED may receive a second power voltage ELVSS.

Although the pixel circuit PC including two thin-film transistors and one storage capacitor may be described with reference to FIG. 4, the disclosure may not be limited thereto. The number of thin-film transistors and the number of storage capacitors may be variously modified according to the design of the pixel circuit PC. For example, in addition to the two thin-film transistors described above, the pixel circuit PC may further include four, five, or more thin-film transistors.

Referring again to FIG. 3, the intermediate area MA may surround the opening area OA in a plan view. The intermediate area MA may be an area in which display elements such as organic light-emitting diodes emitting light may not be disposed, and signal lines providing signals to the sub-pixels P disposed around the opening area OA may pass the intermediate area MA. A scan driver 1100 configured to provide scan signals to each of the sub-pixels P, a data driver 1200 configured to provide data signals to each of the sub-pixels P. and main power wirings (not shown) configured to provide the first power voltage and the second power voltage, and the like, may be disposed in the peripheral area PA. Although FIG. 3 illustrates that the data driver 1200 may be adjacent to a side of the substrate 100, according to an embodiment, the data driver 1200 may be disposed on a flexible printed circuit board (FPCB) electrically connected to a pad disposed at a side of the display device 1.

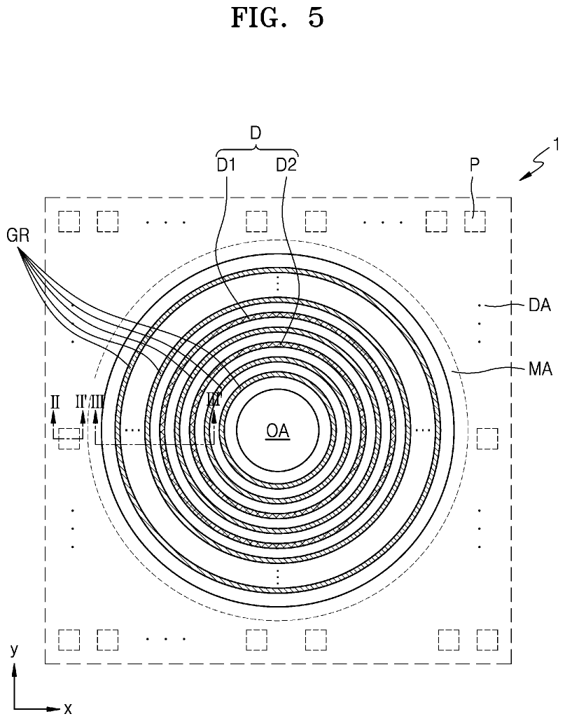

FIG. 5 is a top-plan view schematically illustrating a portion of the display device 1 according to an embodiment. FIG. 5 illustrates the opening area OA of the display device 1, the intermediate area MA surrounding the opening area OA, and the display area DA surrounding the intermediate area MA. Referring to FIG. 5, the sub-pixels P may be disposed in the display area DA, and the intermediate area MA may be disposed between the opening area OA and the display area DA. The sub-pixels P may be aligned in the display area DA to surround the opening area OA and the intermediate area MA.

The sub-pixel P, which may be a smallest area from which light may be emitted, includes an area from which red, green, or blue light may be emitted, and light may be emitted through a light-emitting element, e.g., a light-emitting diode LED. A position of the sub-pixel P may correspond to a position of the light-emitting diode LED. The sub-pixel P being disposed in the display area DA may indicate that the light-emitting diode LED may be disposed in the display area DA.

Sub-pixels P and/or light-emitting diodes LED adjacent to the opening area OA may be spaced apart from one another with reference to the opening area OA in a plan view. The sub-pixels P and/or light-emitting diodes LED may be spaced apart up and down with reference to the opening area OA, or may be spaced apart left and right with reference to the opening area OA.

Grooves GR may be spaced apart from one another in the intermediate area MA. In a plan view (e.g., seen from a direction perpendicular to a top surface of the substrate 100), each of the grooves GR may have a closed-loop shape. In some embodiments, the grooves GR may be aligned in concentric circles, as shown in FIG. 5.

Dams D may be disposed in the intermediate area MA. The dams D may have a closed-loop shape in a plan view. Each of the dams D may be between the grooves GR. In an embodiment, the dam D may include a first dam D1 and a second dam D2. The first dam D1 and the second dam D2 may be disposed in the intermediate area MA. The second dam D2 may be closer to the opening area OA than the first dam D1. The first dam D1 may be disposed between the second dam D2 and the display area DA. In other words, the first dam D1 may be closer to the display area DA than the second dam D2, and the first dam D1 may be disposed between the second dam D2 and the opening area OA. However, the disclosure may not be limited thereto. In an embodiment, in the display panel 10, one or three or more dams D may be disposed in the intermediate area MA. For example, in case that there are three dams D in the intermediate area MA of the display panel 10, the dams D may include a first dam D1, a second dam D2, and a third dam.

The grooves GR may be between the opening area OA and the second dam D2, between the first dam D1 and the second dam D2, or between the display area DA and the first dam D1. In an embodiment, FIG. 5 illustrates that two grooves GR may be between the opening area OA and the second dam D2, one groove GR may be between the first dam D1 and the second dam D2, and multiple grooves GR may be between the display area DA and the first dam D1, but the disclosure may not be limited thereto. For example, four grooves GR may be between the display area DA and the first dam D1. In an embodiment, one or three or more grooves GR may be disposed between the opening area OA and the second dam D2, and two or more grooves GR may be between the first dam D1 and the second dam D2. However, the disclosure may not be limited thereto.

As the substrate 100 of the display panel 10 includes the first through hole 100H corresponding to the opening area OA, it may be deemed that the opening area OA in the corresponds to the first through hole 100H. For example, the grooves GR being between the dam D and the opening area OA may indicate that the grooves GR may be between the dam D and the first through hole 100H.

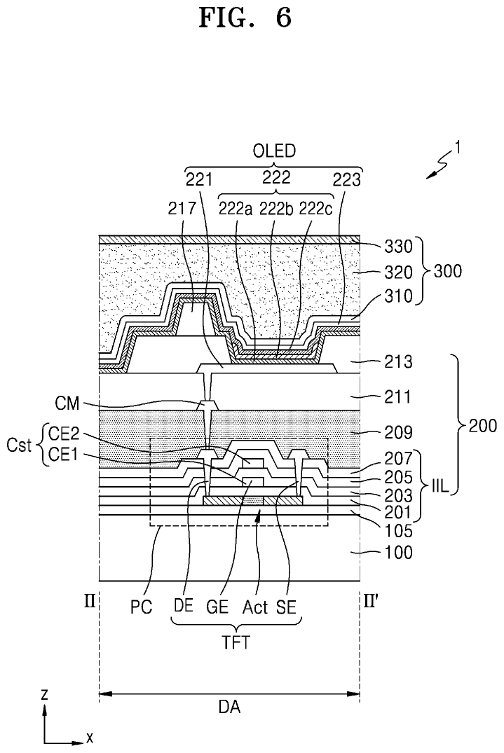

FIG. 6 is a schematic cross-sectional view of a display device according to an embodiment; FIG. 6 corresponds to a schematic cross-sectional view taken along line II-II′ shown in FIG. 5. Referring to FIG. 6, the substrate 100 may include a glass material or a high molecular resin. In case that the substrate 100 includes a high molecular resin, the substrate 100 may include polyethersulfone, polyarylate, polyetherimide, polyethylene naphthalate, polyethylene terephthalate, polyphenylene sulfide, polyimide, polycarbonate, cellulose triacetate, cellulose acetate propionate, the like, or a combination thereof.

Although not shown, the substrate 100 may include a first base layer, a first barrier layer, a second base layer, and a second barrier layer. In an embodiment, the first base layer, the first barrier layer, the second base layer, and the second barrier layer may be sequentially stacked on each other in a direction of a thickness of the substrate 100.

The first barrier layer and the second barrier layer, which may be barrier layers preventing permeation of foreign materials, may include a single layer or multiple layers including an inorganic material such as silicon nitride (SiNₓ), silicon oxide (SiO₂), silicon oxynitride (SiON), or a combination thereof.

A buffer layer 105 formed to prevent permeation of impurities into the semiconductor layer Act of a thin-film transistor TFT may be disposed on the substrate 100. The buffer layer 105 may include an inorganic insulating material such as silicon nitride, silicon oxynitride, silicon oxide, or a combination thereof and may include a single layer or multiple layers including the aforementioned inorganic insulating materials.

The pixel circuit PC may be disposed on the buffer layer 105. The pixel circuit PC may include the thin-film transistor TFT and the storage capacitor Cst. The thin-film transistor TFT may include a semiconductor layer Act, a gate electrode GE, a source electrode SE, and a drain electrode DE. Although the embodiment illustrates a top-gate type thin-film transistor in which the gate electrode GE may be above the semiconductor layer Act with the first insulating layer 201 therebetween, according to an embodiment, the thin-film transistor TFT may instead include a bottom-gate type thin-film transistor.

The semiconductor layer Act may include polysilicon. For example, the semiconductor layer Act may include amorphous silicon, an oxide semiconductor, an organic semiconductor, the like, or a combination thereof. The gate electrode GE may include a low-resistance metal material. The gate electrode GE may include a conductive material including molybdenum (Mo), aluminum (Al), copper (Cu), titanium (Ti), the like, or a combination thereof and may formed into multiple layers or a single layer including the aforementioned materials.

The first insulating layer 201 between the semiconductor layer Act and the gate electrode GE may include an inorganic insulating material such as silicon oxide, silicon nitride, silicon oxynitride, aluminum oxide, titanium oxide, tantalum oxide, hafnium oxide, the like, or a combination thereof. The first insulating layer 201 may include a single layer or multiple layers including the aforementioned materials.

The source electrode SE and the drain electrode DE may include highly conductive materials. The source electrode SE and the drain electrode DE may include a conductive material including Mo, Al, Cu, Ti, the like, or a combination thereof and may be formed into multiple layers or a single layer including the aforementioned materials. For example, the source electrode SE, the drain electrode DE, and the data line DL may be formed into a multiple-layer structure including a titanium layer, an aluminum layer, and a titanium layer (Ti/Al/Ti).

The storage capacitor Cst may include a lower electrode CE1 and an upper electrode CE2 overlapping each other with the second insulating layer 203 therebetween. The storage capacitor Cst may overlap the thin-film transistor TFT. Regarding this, FIG. 6 illustrates that the gate electrode GE of the thin-film transistor TFT includes the lower electrode CE of the storage capacitor Cst. As an embodiment, the storage capacitor Cst may instead not overlap the thin-film transistor TFT. The storage capacitor Cst may be covered with a third insulating layer 205. The upper electrode CE2 of the storage capacitor Cst may include a conductive material including Mo, Al, Cu, Ti, the like, or a combination thereof and may include multiple layers or a single layer including the aforementioned materials.

A fourth insulating layer 207 may be disposed on the third insulating layer 205. The second insulating layer 203, the third insulating layer 205, and the fourth insulating layer 207 may include an inorganic insulating material such as silicon oxide, silicon nitride, silicon oxynitride, aluminum oxide, titanium oxide, tantalum oxide, hafnium oxide, the like, or a combination thereof. The second insulating layer 203, the third insulating layer 205, and the fourth insulating layer 205 may include a single layer or multiple layers including the aforementioned materials. However, the disclosure may not be limited thereto. Although not shown, a fifth insulating layer may be disposed on the fourth insulating layer 205. A gate electrode may be disposed on the fourth insulating layer 205.

The pixel circuit PC including the thin-film transistor TFT and the storage capacitor Cst may be covered by a first organic insulating layer 209. The first organic insulating layer 209 may include a surface in which a top thereof may be approximately flat.

The pixel circuit PC may be electrically connected to a pixel electrode 221. For example, as shown in FIG. 6, a contact metal layer CM may be between the thin-film transistor TFT and the pixel electrode 221. The contact metal layer CM may contact the thin-film transistor TFT through a contact hole formed in the first organic insulating layer 209, and the pixel electrode 221 may contact the contact metal layer CM through a contact hole formed in a second organic insulating layer 211 disposed on the contact metal layer CM. The contact metal layer CM may include a conductive material including Mo, Al, Cu, Ti, the like, or a combination thereof and may be formed into multiple layers or a single layer including the aforementioned materials. As an embodiment, the contact metal layer CM may be formed into multiple layers including Ti/Al/Ti.

The first organic insulating layer 209 and the second organic insulating layer 211 may include a general-purpose polymer such as polymethylmethacrylate (PMMA), polystyrene (PS), or a combination thereof, a polymer derivative having a phenol group, an acryl-based polymer, an imide-based polymer, an aryl ether-based polymer, an amide-based polymer, a fluorine-based polymer, a p-xylene-based polymer, a vinyl alcohol-based polymer, or a blend thereof. As an embodiment, the first organic insulating layer 209 and the second organic insulating layer 211 may include polyimide.

The pixel electrode 221 may be formed on the second organic insulating layer 211. The pixel electrode 221 may include a conductive oxide material such as indium tin oxide (ITO), indium zinc oxide (IZO), zinc oxide (ZnO), indium oxide (In₂O₃), indium gallium oxide (IGO), aluminum zinc oxide (AZO) or a combination thereof. As an embodiment, the pixel electrode 221 may include a reflective film including silver (Ag), magnesium (Mg), aluminum (Al), platinum (Pt), palladium (Pd), gold (Au), nickel (Ni), neodymium (Nd), iridium (Ir), chromium (Cr), a compound thereof or a combination thereof. As an embodiment, the pixel electrode 221 may further include a film formed of ITO, IZO, ZnO, In₂O₃, or a combination thereof above/under the aforementioned reflective film.

A third organic insulating layer 213 may be formed on the pixel electrode 221. The third organic insulating layer 213 may include a pixel defining film defining an emission area of a pixel. The third organic insulating layer 213 may include an opening exposing at least a portion of a top surface of the pixel electrode 221 and may cover an edge of the pixel electrode 221. The third organic insulating layer 213 may include an organic insulating material. For example, the third organic insulating layer 213 may also include an inorganic insulating material such as silicon nitride (SiNₓ), silicon oxynitride (SiON), silicon oxide (SiOₓ), or a combination thereof. For example, the third organic insulating layer 213 may include an organic insulating material and an inorganic insulating material.

An intermediate layer 222 includes an emission layer 222b. The intermediate layer 222 may also include a first functional layer 222a disposed under the emission layer 222b and/or a second functional layer 222c disposed on the emission layer 222b. The emission layer 222b may include a high-molecular or low-molecular organic material emitting light of certain colors.

The first functional layer 222a may include a single layer or multiple layers. For example, in case that the first functional layer 222a is formed of a high-molecular material as a hole transport layer (HTL), the first functional layer 222a may be formed of poly-(3,4)-ethylene-dihydroxythiophene (PEDOT), polyaniline (PANI), or a combination thereof. In case that the first functional layer 222a is formed of a low-molecular material, the first functional layer 222a may include a hole injection layer (HIL) and a hole transport layer (HTL).

The second functional layer 222c may not be always provided. For example, in case that the first functional layer 222a and the emission layer 222b are formed of a high molecular material, it is desirable to form the second functional layer 222c. The second functional layer 222c may include a single layer or multiple layers. The second functional layer 222c may include an electron transport layer and/or an electron injection layer (EIL).

The emission layer 222b from among the intermediate layer 222 may be disposed in each pixel in the display area DA. The emission layer 222b may be patterned to correspond to the pixel electrode 221. Unlike the emission layer 222b, the first functional layer 222a and/or the second functional layer 222c of the intermediate layer 222 may extend toward the intermediate area MA to be disposed in the intermediate area MA, as well as in the display area DA.

The counter electrode 223 may include a conductive material having a small work function. For example, the counter electrode 223 may include a (semi)transparent layer including Ag, Mg, Al, Pt, Pd, Au, Ni, Nd, Ir, Cr, Li, Ca, an alloy thereof, or a combination thereof. For example, the counter electrode 223 may further include a layer including TIO, IZO, ZnO, In₂O₃, or a combination thereof on the (semi)transparent layer including the aforementioned materials. The counter electrode 223 may be formed in the intermediate area MA, as well as in the display area DA. The first functional layer 222a, the second functional layer 222c, and the counter electrode 223 may be formed through a thermal deposition technique.

Although not shown, a capping layer may be on the counter electrode 223. For example, the capping layer may include LiF, and may be formed through a thermal deposition method. In some embodiments, the capping layer may be omitted.

A fourth organic insulating layer 217 may be formed on the third organic insulating layer 213. The fourth organic insulating layer 217 may include an organic insulating material such as polyimide. For example, the fourth organic insulating layer 217 may also include an inorganic insulating material, or may include an organic insulating material or inorganic insulating material. The fourth organic insulating layer 217 may include a material that may be identical to or different from a material included in the third organic insulating layer 213. As an embodiment, the third organic insulating layer 213 and the fourth organic insulating layer 217 may include polyimide. The third organic insulating layer 213 and the fourth organic insulating layer 217 may be formed together in a mask process using a halftone mask.

The organic light-emitting diode OLED may be covered by the encapsulation layer 300. The encapsulation layer 300 may include at least one organic encapsulation layer and at least one inorganic encapsulation layer, and FIG. 6 illustrates that the encapsulation layer 300 includes a first inorganic encapsulation layer 310, a second inorganic encapsulation layer 330, and an organic encapsulation 320 therebetween. In other embodiments, the numbers and stack orders of organic encapsulation layers and inorganic encapsulation layers may be modified.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, silicon oxynitride, and a combination thereof. The first inorganic encapsulation layer 310 and the second inorganic encapsulation layer 330 may include a single layer or multiple layers including the aforementioned materials. The organic encapsulation 320 may include a polymer-based material. The polymer-based material may include an acryl-based resin such as polymethylmethacrylate, polyacrylate, an epoxy-based resin, polyimide, polyethylene, the like, or a combination thereof. As an embodiment, the organic encapsulation 320 may include acrylate polymer.

The first inorganic encapsulation layer 310 and the second inorganic encapsulation layer 330 may respectively include different materials. For example, the first inorganic encapsulation layer 310 may include silicon oxynitride, and the second inorganic encapsulation layer 330 may include silicon nitride. The first inorganic encapsulation layer 310 and the second inorganic encapsulation layer 330 may have different thicknesses. A thickness of the first inorganic encapsulation layer 310 may be greater than a thickness of the second inorganic encapsulation layer 330. Instead, a thickness of the second inorganic encapsulation layer 330 may be greater than a thickness of the first inorganic encapsulation layer 310, or the first inorganic encapsulation layer 310 and the second inorganic encapsulation layer 330 may have a same thickness.

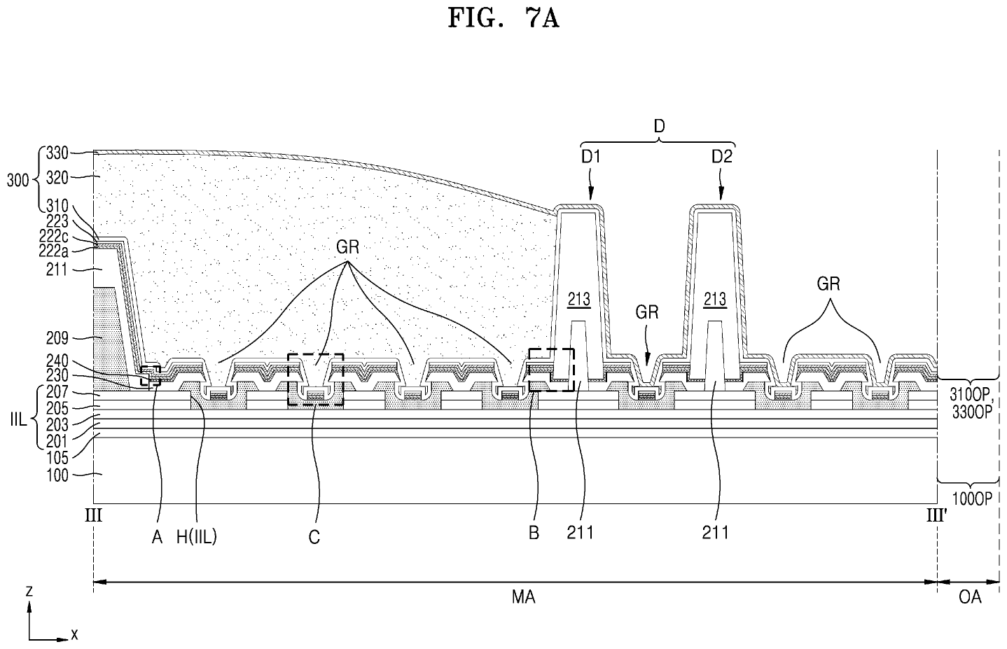

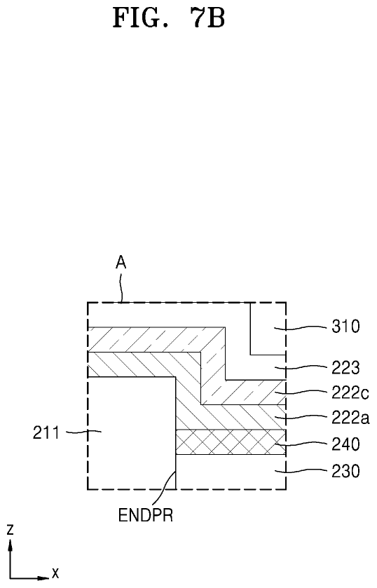

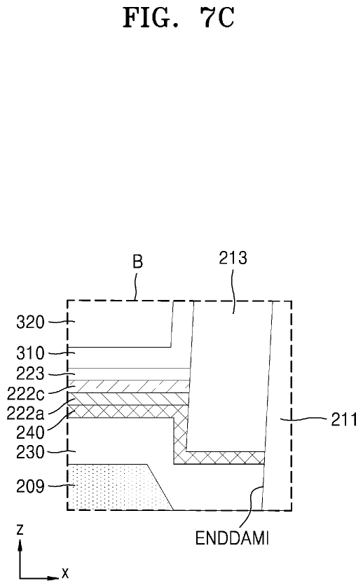

FIGS. 7A to 7C are schematic cross-sectional views illustrating a display device according to an embodiment. More particularly, FIG. 7A illustrates a schematic cross-section of a display panel according to an embodiment taken along line III-III of FIG. 5 and FIGS. 7B and 7C are enlarged schematic cross-sectional views illustrating portions A and B shown in FIG. 7A, respectively. Referring to FIGS. 7A to 7C, the first dam D1, the second dam D2, grooves GR, and step portions of the metal layer 230 disposed in the grooves GR may be disposed in the intermediate area MA. The dams may include the first dam D1 and the second dam D2. However, the disclosure may not be limited thereto. One, three, or four or more dams may be in the intermediate area MA. For example, the third dam may be between the second dam D2 and the opening area OA.

In an embodiment, the first dam D1 and the second dam D2 may include a same material. The first dam D1 and the second dam D2 may include the second organic insulating layer 211 and the third organic insulating layer 213 that may be sequentially stacked on each other. In other words, the first dam D1 and the second dam D2 may include a structure in which the second organic insulating layer 211 and the third organic insulating layer 213 may be sequentially stacked on each other. However, the disclosure may not be limited thereto. In an embodiment, the third dam disposed between the second dam D2 and the opening area OA may be provided as including the third organic insulating layer 213.

The first dam D1 and the second dam D2 may be provided having a relatively great height. As the first dam D1 and the second dam D2 may be provided having a relatively great height, leakage of a monomer forming the organic encapsulation layer 320 to a cutting line may be reduced as much as possible or may be prevented. Although FIG. 7A illustrates that the first dam D1 prevents leakage of the monomer forming the organic encapsulation layer 320, the disclosure may not be limited thereto. In an embodiment, the second dam D2 may instead prevent leakage of the monomer forming the organic encapsulation layer 320.

In an embodiment, the first dam D1 may be between the display area DA and the opening area OA. The first dam D1 may be disposed around the opening area OA. The second dam D2 may be disposed between the first dam D1 and the opening area OA. The second dam D2 may be disposed around the opening area OA.

In an embodiment, the buffer layer 105 and inorganic insulating layers IIL may be disposed on the substrate 100. The inorganic insulating layers IIL may include the first insulating layer 201, the second insulating layer 203, the third insulating layer 205, and the fourth insulating layer 207. Holes H(IIL) (or recesses) penetrating the third insulating layer 205 and the fourth insulating layer 207 may be defined in the third insulating layer 205 and the fourth insulating layer 207 in the intermediate area MA. However, the disclosure may not be limited thereto. In an embodiment, the inorganic insulating layers IIL may include the first insulating layer 201, the second insulating layer 203, the third insulating layer 205, the fourth insulating layer 207, and the fifth insulating layer. The fifth insulating layer may be on the fourth insulating layer 207. Holes penetrating the fourth insulating layer 207 and the fifth insulating layer may be defined in the fourth insulating layer 207 and the fifth insulating layer of the intermediate area MA.

The holes H(IIL) of the inorganic insulating layer IIL may be filled with the first organic insulating layer 209. The grooves GR may be formed in a top surface of the first organic insulating layer 209. In other words, the grooves GR may be formed in the top surface of the first organic insulating layer 209 disposed in the holes H(IIL) of the inorganic insulating layer IIL. In an embodiment, four holes H(IIL) may be defined in the inorganic insulating layer IIL between the first dam D1 and the display area DA, and four grooves GR may be formed in the top surface of the first organic insulating layer 209. One hole H(IIL) may be defined in the inorganic insulating layer IIL between the first dam D1 and the second dam D2, and one groove GR may be formed in the top surface of the first organic insulating layer 209. Two holes H(IIL) may be defined in the inorganic insulating layer IIL between the second dam D2 and the opening area OA, and two grooves GR may be formed in the top surface of the first organic insulating layer 209. However, the disclosure may not be limited thereto. Five or more holes H(IIL) may be defined in the inorganic insulating layer IIL between the first dam D1 and the display area DA, and five or more grooves GR may be formed in the top surface of the first organic insulating layer 209. Two or more holes H(IIL) may be defined in the inorganic insulating layer IIL between the first dam D1 and the second dam D2, and two or more grooves GR may be formed in the top surface of the first organic insulating layer 209. Two or more holes H(IIL) may be defined in the inorganic insulating layer IIL between the second dam D2 and the opening area OA, and two or more grooves GR may be formed in the first organic insulating layer 209. Although not shown, in an embodiment, in case that the display panel 10 includes the third dam between the second dam D2 and the opening area OA, one hole H(IIL) may be defined in the inorganic insulating layer IIL between the second dam D2 and the third dam, one groove GR may be formed in the top surface of the first organic insulating layer 209, one hole H(IIL) may be defined in the inorganic insulating layer IIL between the third dam and the opening area OA, and one groove GR may be formed in the top surface of the first organic insulating layer 209. However, the disclosure may not be limited thereto.

In an embodiment, a metal layer 230 may be disposed on the first organic insulating layer 209. The metal layer 230 may include a same material as a material of the contact metal layer CM in the schematic cross-sectional view of the display area DA shown in FIG. 6, and the metal layer 230 and the contact metal layer CM may be simultaneously patterned and formed in a same process. The metal layer 230 may include a conductive material including Mo, Al, Cu, Ti, the like, or a combination thereof and may include multiple layers or a single layer including the aforementioned materials. As an embodiment, the metal layer 230 may be formed into a multi-layer including Ti/Al/Ti. The metal layer 230 may include end portions ENDGR or end portions ENDGR corresponding to a groove GR. The end portions ENDGR of the metal layer 230 may be spaced apart from one another above the grooves GR in the first organic insulating layer 209. As the metal layer 230 includes the end portions ENDGR and may be disposed at a location corresponding to the grooves GR in the first organic insulating layer 209, the functional layers (i.e., the first functional layer 222a and the second functional layer 222c) and the counter electrode 223 extending from the display area DA toward the intermediate area MA may be short-circuited. As the functional layers (i.e., the first functional layer 222a and the second functional layer 222c) and the counter electrode 223 may be short-circuited in the intermediate area MA by the end portions ENDGR of the metal layer 230, permeation of moisture or foreign air into the display area DA through the functional layers (i.e., the first functional layer 222a and the second functional layer 222c) and the counter electrode 223 may be prevented, and by doing so, the reliability of the display area DA may be secured. As the end portions ENDGR of the metal layer 230 having the functional layers (i.e., the first functional layer 222a and the second functional layer 222c) and the grooves GR in the first organic insulating layer 209 may be simultaneously patterned in case that the contact metal layer CM and the first organic insulating layer 209 are formed in the display area DA, a structure in which the functional layers (i.e., the first functional layer 222a and the second functional layer 222c) and the counter electrode 223 may be produced without using additional masks.

In an embodiment, a protective layer 240 may be disposed on the metal layer 230. Top surfaces and side surfaces of the end portions ENDGR of the metal layer 230 may be covered by the protective layer 240. In other words, the top surface and side surfaces of the metal layer 230 may be covered with the protective layer 240. The protective layer 240 may include a same material as a material of the pixel electrode 221 of the organic light-emitting diode OLED disposed in the display area DA of the display panel 10. The protective layer 240 may be simultaneously patterned and formed in a same process with the pixel electrode 221 of the organic light-emitting diode OLED disposed in the display area DA of the display panel 10. The protective layer 240 may include a conductive oxide material such as indium tin oxide (ITO), indium zinc oxide (IZO), zinc oxide (ZnO), indium oxide (In₂O₃), indium gallium oxide (IGO), aluminum zinc oxide (AZO), or a combination thereof. As an embodiment, the protective layer 240 may include a reflective film including Ag. Mg. Al, Pt, Pd, Au, Ni, Nd, Ir, Cr, a compound thereof, or a combination thereof. As an embodiment, the protective layer 240 may further include a film formed of ITO, IZO, ZnO, In₂O₃, or a combination thereof above/under the aforementioned reflective film. In case that Al of side surfaces of the metal layer 230 is exposed to an etchant or a developer and undergoes etching in the process of manufacturing the display panel 10, an undercut structure may be formed between Ti and Al of the metal layer 230, and therefore defects may occur in subsequent layers. As the side surfaces of the metal layer 230 may be covered by the protective layer 240, exposure of Al of the metal layer 230 to the etchant or developer in the process of manufacturing the display panel 10 may be prevented, and by doing so, occurrence of defects in the subsequent layers due to etching of Al of the metal layer 230 may be prevented. The aluminum layer of the metal layer 230 may cause defective factors through a reduction reaction with Ag included in the protective layer 240. As the side surfaces of the metal layer 230 may be covered by the protective layer 240, exposure of Al of the metal layer 230 may be prevented, and accordingly, occurrence of defects on the display panel 10 may be fundamentally prevented.

As the protective layer 240 may also be short-circuited by the end portions ENDGR included in the metal layer 230, the protective layer 240 may also be disposed at a location corresponding to the grooves GR in the first organic insulating layer 209. The functional layers (i.e., the first functional layer 222a and the second functional layer 222c) and the counter electrode 223 extending from the display area DA toward the intermediate area MA may be disposed on the protective layer 240. As the functional layers (i.e., the first functional layer 222a and the second functional layer 222c) and the counter electrode 223 may be short-circuited at the end portions ENDGR of the metal layer 230, the functional layers (i.e., the first functional layer 222a and the second functional layer 222c) and the counter electrode 223 may be disposed at locations corresponding to the grooves GR in the first organic insulating layer 209. In other words, the protective layer 240, the functional layers (i.e., the first functional layer 222a and the third functional layer 222c) and the counter electrode 223 may be disposed above the grooves GR in the first organic insulating layer 209. The protective layer 240, the functional layers (i.e., the first functional layer 222a and the second functional layer 222c) and the counter electrode 223 may be sequentially disposed on each other at a location corresponding to the grooves GR in the first organic insulating layer 209.

In an embodiment, the first organic insulating layer 209 and the second organic insulating layer 211 may contact (e.g., directly contact) each other at a point of the display area DA from which the intermediate area MA begins. In other words, the first organic insulating layer 209 and the second organic insulating layer 211 may contact (e.g., directly contact) each other in a portion of the intermediate area MA adjacent to the display area DA. In the portion of the intermediate area MA adjacent to the display area DA, ends of the first organic insulating layer 209 and the second organic insulating layer 211 may be above the inorganic insulating layer IIL of the intermediate area MA. In other words, in the portion of the intermediate area MA adjacent to the display area DA, the ends of the first organic insulating layer 209 and the second organic insulating layer 211 may be above the fourth insulating layer 207. In a process of manufacturing the display panel 10, the metal layer 230 may be formed after the first organic insulating layer 209 may be formed, and then, the second organic insulating layer 211 and the protective layer 240 may be sequentially formed. As the second organic insulating layer 211 may be formed after the metal layer 230 may be formed, in the portion of the intermediate area MA adjacent to the display area DA, a side surface of the end of the second organic insulating layer 211 and a side surface of an end ENDPR (i.e., a peripheral end or end portion ENDPR of metal layer 230 corresponding to outer periphery of intermediate area MA) of the metal layer 230 may contact each other. In the following processes, as the top surface and side surfaces of the metal layer 230 may be covered by the protective layer 240, the top surface and the side surfaces of the end ENDPR of the metal layer 230 contacting the end of the second organic insulating layer 211 may be covered by the protective layer 240 (see FIG. 7B). In detail, the side surfaces and top surface of the end ENDPR of the metal layer 230 at the point of the display area DA at which the intermediate area MA begins may be covered by the second organic insulating layer 211 and the protective layer 240.

Referring now to FIG. 7C, the first dam D1 may include the third organic insulating layer 213. The third organic insulating layer 213 of the first dam D1 may be formed after the metal layer 230 and the protective layer 240 are formed. Accordingly, an end of the third organic insulating layer 213 of the first dam D1 may be above the protective layer 240. The third organic insulating layer 213 of the first dam D1 may cover the ends ENDDAM1 of the metal layer 230 (or end portions ENDDAM1 of metal layer 230 that correspond to first dam D1) and the protective layer 240 contacting the third organic insulating layer 213. More particularly, the ends ENDDAM1 of the metal layer 230 and the protective layer 240 contacting the first dam D1 in the intermediate area MA may be covered by the third organic insulating layer 213 included in the first dam D1. However, the disclosure may not be limited thereto.

Referring now to FIG. 7A, a length in the first direction (e.g., the x direction or −x direction) from a point in the display area DA at which the metal layer 230 begins from the display area DA to the first dam D1 may be about 59.5 um. The length of the first dam D1 in the first direction (e.g., the x direction or −x direction) may be about 30 um. A length in the first direction (e.g., the x direction or −x direction) between the first dam D1 and the second dam D2 may be about 15.5 um. A length in the first direction (e.g., the x direction or −x direction) of the second dam D2 may be about 30 um. A length in the first direction (e.g., the x direction or −x direction) from the second dam D2 to the opening area OA may be about 51 um. In an embodiment, the display panel 10 may include the third dam between the second dam D2 and the opening area OA. A length in the first direction (e.g., the x direction or −x direction) between the second dam D2 and the third dam may be about 15.5 um. A length in the first direction (e.g., the x direction or −x direction) of the third dam may be about 20 um. A length in the first direction (e.g., the x direction or −x direction) between the third dam and the opening area OA may be about 15.5 um. However, the disclosure may not be limited thereto.

In an embodiment, some of the grooves GR formed in the top surface of the first organic insulating layer 209 filling the holes H(IIL) defined in the inorganic insulating layer IIL in the intermediate area MA may be covered by the organic encapsulation layer 320. In case that flow of the monomer of the organic encapsulation layer 320 is interrupted by the first dam D1, the grooves GR in the first organic insulating layer 209 between the first dam D1 and the display area DA may be covered by the organic encapsulation layer 320. In other embodiments, in case that the flow of the monomer of the organic encapsulation layer 320 is interrupted by the second dam D2, the grooves GR in the first organic insulating layer 209 between the first dam D1 and the display area DA and the grooves GR in the first organic insulating layer 209 between the first dam D1 and the second dam D2 may also be covered by the organic encapsulation layer 320.

The first inorganic encapsulation layer 310 of the encapsulation layer 300 may continuously cover inner surfaces of the grooves GR in the first organic insulating layer 209, and the organic encapsulation layer 320 may cover a portion of the intermediate area MA. The first inorganic encapsulation layer 310 may continuously cover the intermediate area MA. However, as described above, the organic encapsulation layer 320 may cover the grooves GR in the first organic insulating layer 209 between the first dam D1 and the display area DA and the grooves GR in the first organic insulating layer 209 between the first dam D1 and the second dam D2. The second inorganic encapsulation layer 330 may entirely cover the intermediate area MA.

The flow of the monomer may be controlled through the first dam D1 or the second dam D2 in case that the organic encapsulation layer 320 is formed. In the intermediate area MA, the organic encapsulation layer 320 may be discontinuous due to the first dam D1 and the second dam D2. An end portion of the organic encapsulation layer 320 may be at a side of the first dam D1 or the second dam D2. The organic encapsulation layer 320 may not extend toward the opening area OA via the first dam D1 or the second dam D2. A portion of the second inorganic encapsulation layer 330 may contact (e.g., directly contact) a portion of the first inorganic encapsulation layer 310 on the first dam D1 or the second dam D2. However, the disclosure may not be limited thereto.

Referring to the opening area OA shown in FIG. 7A, the display panel 10 may include the opening area OA. The opening area OA of the display panel 10 may include openings of components included in the display panel 10. For example, openings of the display panel 10 may include an opening 100OP (corresponding to first through hole 100H of FIG. 2) of the substrate 100, an opening 310OP of the first inorganic encapsulation layer 310 and an opening 330OP of the second inorganic encapsulation layer 330 (corresponding to third through hole 300H of FIG. 2) in the encapsulation layer 300.

The schematic cross-sectional view of the display device 1 shown in FIG. 7A may be understood as a schematic cross-sectional view of a structure surrounding the opening area OA. For example, seen in a direction perpendicular to the top surface of the substrate 100 (i.e., in a plan view), the grooves GR shown in FIG. 7A may have a shape of a loop surrounding the opening area OA, as shown in FIG. 5. In other words, seen in the direction perpendicular to the top surface of the substrate 100 (i.e., in a plan view), the grooves GR may have a closed-loop shape surrounding the opening area OA. Seen in the direction perpendicular to the top surface of the substrate 100 (i.e., in a plan view), the first dam D1 and the second dam D2 may also have a loop shape surrounding the opening area OA. In other words, seen in the direction perpendicular to the top surface of the substrate 100 (i.e., in a plan view), the first dam D1 and the second dam D2 may have a closed-loop shape surrounding the opening area OA.

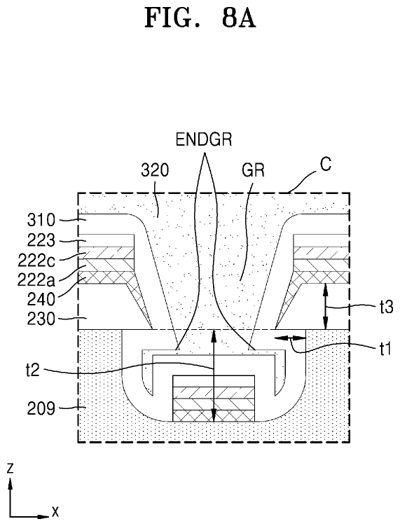

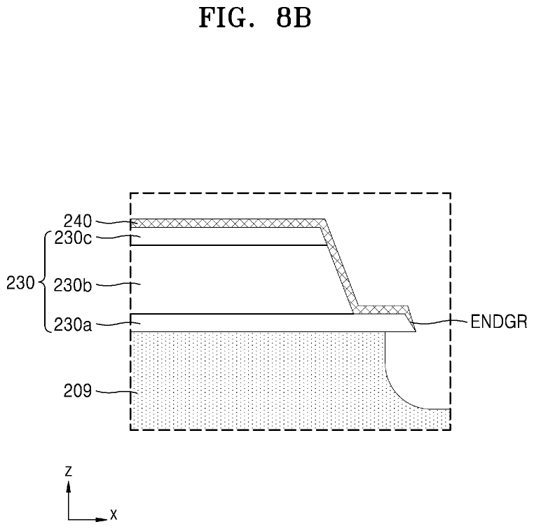

FIG. 8A is a schematic cross-sectional view illustrating an enlarged image of a region ‘C’ shown in FIG. 7A, and FIG. 8B is a schematic cross-sectional view of an enlarged image of a region shown in FIG. 8A. More particularly, FIG. 8B is a schematic cross-sectional view illustrating an enlarged image of a vicinity about end portion ENDGR of the metal layer 230 shown in FIG. 8A.

Referring to FIG. 8A, the protective layer 240 may be not disposed on at least a portion of the first organic insulating layer 209 adjacent to the end portion ENDGR of the metal layer 230. As the protective layer 240 is not disposed on at least the portion of the first organic insulating layer 209 adjacent to the end portion ENDGR of the metal layer 230, gas (or outgas) generated by the first organic insulating layer 209 in a process of manufacturing the display device may be discharged outside, and accordingly defects may not occur in the first organic insulating layer 209.

A process of forming the end portion ENDGR of the metal layer 230 and the groove GR in the first organic insulating layer 209 may include a first process and a second process. The first process may include a process of forming the end portion ENDGR of the metal layer 230 by etching at least a portion of the metal layer 230 arranged in contact with a top surface of the first organic insulating layer 209. The second process may include a process of forming the groove GR in the first organic insulating layer 209 by etching at least a portion of the first organic insulating layer 209. The second process may be performed after the first process, however the embodiments may not be limited thereto. In the first process of forming the end portion ENDGR of the metal layer 230 by etching at least the portion of the metal layer 230, at least the portion of the first organic insulating layer 209 may be simultaneously etched, and thus the groove GR in the first organic insulating layer 209 may be formed.

A minimum distance t2 from a bottom surface of the metal layer 230 to the groove GR in the first organic insulating layer 209 (i.e., a top surface of a recessed or groove GR portion of first organic insulating layer 209) may be greater than a length t1 to which the end portion ENDGR of the metal layer 230 protrudes in a direction toward the groove GR in the first organic insulating layer 209. A depth of the groove GR (i.e., the minimum distance t2 from the bottom surface of the metal layer 230 to the groove GR in the first organic insulating layer 209) may include a depth t2 to which the first organic insulating layer 209 is etched in the third direction (e.g., the z direction or the −z direction) in the process (or the first process) of forming the end portion ENDGR of the metal layer 230 by etching at least a portion of the metal layer 230 arranged in contact with the top surface of the first organic insulating layer 209 and the process (or the second process) of forming the groove GR in the first organic insulating layer 209 by etching at least the portion of the first organic insulating layer 209. The length t1 to which the end portion ENDGR of the metal layer 230 protrudes inward toward the groove GR in the first organic insulating layer 209 may include the length t1 to which the first organic insulating layer 209 is etched in the first direction (e.g., the x direction or the −x direction) in the process of etching at least the portion of the first organic insulating layer 209 to form the groove GR in the first organic insulating layer 209. While the minimum distance from the bottom surface of the metal layer 230 to the groove GR in the first organic insulating layer 209 (e.g., the depth of the groove GR) may include the length t2 to which the first organic insulating layer 209 is etched in the third direction (e.g., the z direction or the −z direction) while performing the two processes (i.e., the first process and the second process) the length t1 to which the end portion ENDGR of the metal layer 230 protrudes inward in the direction toward the groove GR in the first organic insulating layer 209 may include the length t1 to which the first organic insulating layer 209 is etched in the first direction (e.g., the x direction or the −x direction) while performing one process (i.e., the second process). Accordingly, the minimum distance t2 from the bottom surface of the metal layer 230 to the groove GR in the first organic insulating layer 209 may be greater than the length t1 to which the end portion ENDGR of the metal layer 230 protrudes inward from the first organic insulating layer 209 in the direction toward the groove GR in the first organic insulating layer 209.

The length t1 to which the end portion ENDGR protrudes in the direction toward the groove GR in the first organic insulating layer 209 may be about 2.0 um or less. When the length t1 to which the end portion ENDGR of the metal layer 230 protrudes in the direction toward the groove GR in the first organic insulating layer 209 is greater than about 2.0 um, the length t1 in the first direction (e.g., the x direction or the −x direction) of the end portion ENDGR of the metal layer 230 increases, and therefore, in the process of manufacturing the display device, the end portion ENDGR of the metal layer 230 receives stress, and at least a portion of the end portion ENDGR of metal layer 230 may be damaged.

A thickness t3 of the metal layer may be about 300 Å or more. When the thickness t3 of the metal layer 230 is less than about 300 Å, the metal layer 230 may be broken due to overstress after the first process of etching the metal layer 230 and in the second process of etching the first organic insulating layer 209 to form the groove GR in the first organic insulating layer 209 and to form the end portion ENDGR of the metal layer 230.

Referring to FIG. 8B, the metal layer 230 may include a first layer 230a, a second layer 230b, and a third layer 230c. The third layer 230c may be stacked on the first layer 230a, and the second layer 230b may be disposed between the first layer 230a and the third layer 230c. The first layer 230a may include titanium (Ti), the second layer 230b may include aluminum (Al), and the third layer 230c may include titanium (Ti). In the process (or the first process and the second process) of etching at least the portion of the metal layer 230 and at least the portion of the first organic insulating layer 209, as the first layer 230a and the second layer 230b include different materials, the first layer 230a and the second layer 230b may be etched to different degrees, and the first layer 230a and the second layer 230b may further protrude in the direction toward the groove GR in the first organic insulating layer 209 as compared with the third layer 230c. In other words, a step difference may be generated between the first layer 230a and the second layer 230b included in the metal layer 230.

The protective layer 240 may cover the top surface and side surfaces of the metal layer 230. The step difference between the first layer 230a and the second layer 230b included in the metal layer 230 may also be covered by the protective layer 240. As side surfaces of the step difference between the first layer 230a and the second layer 230b generated by the process of etching the metal layer 230 and the first organic layer 209 may be covered by the protective layer 240, it is possible to prevent further etching of the second layer 230b of the metal layer and to prevent an occurrence of defects in the subsequent processes due to exposure of the second layer 230b in the metal layer 230 to an etchant or a developer.

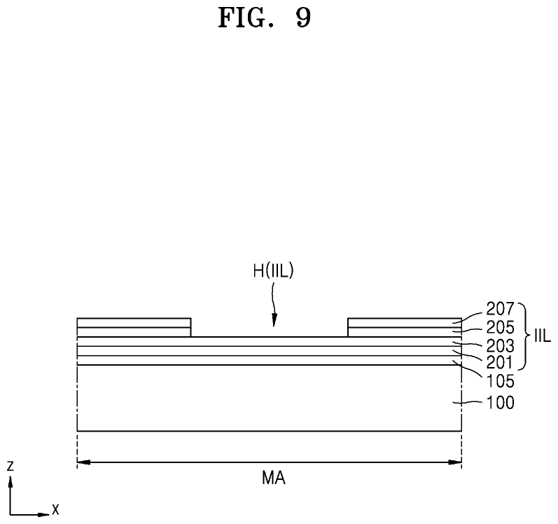

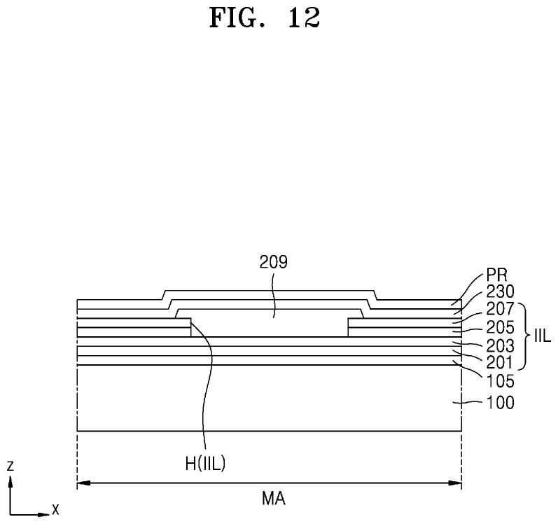

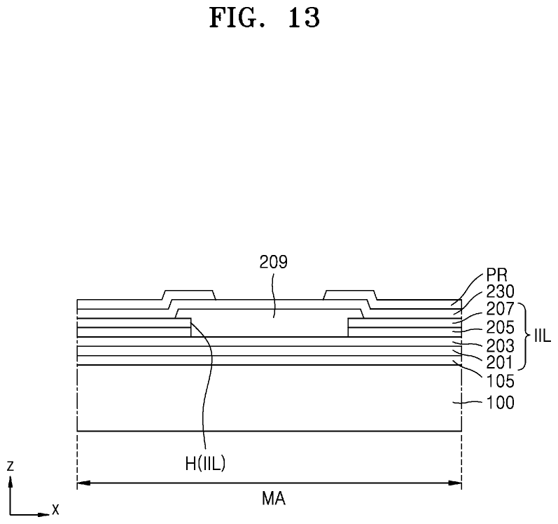

FIGS. 9 to 15 are schematic cross-sectional views illustrating a method of manufacturing the display device 1. Hereinafter, the method of manufacturing the display device 1 will be described with reference to FIGS. 9 to 15.

The method of manufacturing the display device 1 according to an embodiment may include forming the inorganic insulating layer IIL on the substrate 100 including the opening area OA, the display area DA surrounding at least a portion of the opening area OA, and the intermediate area MA between the opening area OA and the display area DA; forming the holes H(IIL) by removing a portion of the inorganic insulating layer IIL in the intermediate area MA; forming the first organic insulating layer 209 in the holes H(IIL) of the inorganic insulating layer IIL; forming the metal layer 230 on the first organic insulating layer 209; forming end portions ENDGR of the metal layer 230 by etching at least a portion of the metal layer 230 formed above the holes H(IIL) of the inorganic insulating layer IIL; and forming on the metal layer 230 the protective layer 240 covering the top surfaces and side surfaces of the end portions ENDGR of the metal layer 230.

Referring to FIG. 9, the buffer layer 105, the first insulating layer 201, the second insulating layer 203, the third insulating layer 205, and the fourth insulating layer 207 may be sequentially formed on the substrate 100. The buffer layer 105, the first insulating layer 201, the second insulating layer 203, the third insulating layer 205, and the fourth insulating layer 207 may each include an inorganic insulating material such as silicon oxide, silicon nitride, silicon oxynitride, aluminum oxide, titanium oxide, tantalum oxide, hafnium oxide, the like, or a combination thereof. However, the disclosure may not be limited thereto. Although not shown, in an embodiment, the fifth insulating layer may also be on the fourth insulating layer 207.

In an embodiment, at least a portion of each of the third insulating layer 205 and the fourth insulating layer 207 may be removed, and the hole H(IIL) or recess penetrating the third insulating layer 205 and the fourth insulating layer 207 may be defined. However, the disclosure may not be limited thereto. In case that the fifth insulating layer is on the fourth insulating layer 207, at least a portion of each of the fourth insulating layer 207 and the fifth insulating layer may be removed, and thus, the hole H(IIL) penetrating the fourth insulating layer 207 and the fifth insulating layer may be defined.

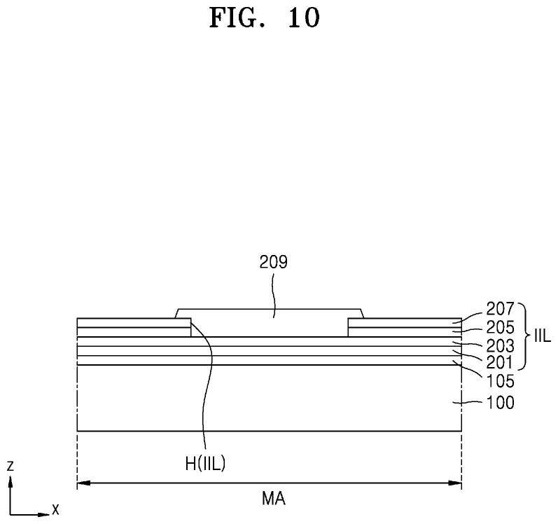

Referring to FIG. 10, the first organic insulating layer 209 may fill the holes H(IIL) defined in the inorganic insulating layer IIL. To fill the holes H(IIL) defined in the inorganic insulating layer IIL with the first organic insulating layer 209, a material for forming the first organic insulating layer 209 may first be disposed on the substrate 100. Light may be irradiated to a portion of the material for forming the first organic insulating layer 209 filling the hole H(IIL) of the inorganic insulating layer IIL, and light may be not irradiated to another portion of the material for forming the first organic insulating layer 209. The portion of the material for forming the first organic insulating layer 209, to which the light may be irradiated, may be cured, and the portion to which the light may not be irradiated may be removed. By irradiating the light only to the portion of the material for forming the first organic insulating layer 209 filling the hole H(IIL) of the inorganic insulating layer IIL, the first organic insulating layer 209 filling the hole H(IIL) of the inorganic insulating layer IIL may be formed. However, the disclosure may not be limited thereto.

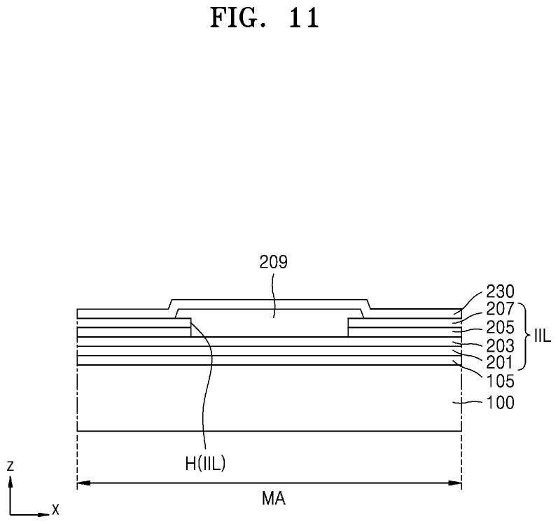

FIGS. 11 to 14 illustrate a process in which the end portions ENDGR may be formed in the metal layer 230 disposed on the first organic insulating layer 209 and a process in which the grooves may be formed as a portion of the first organic insulating layer 209 under the metal layer 230 may be simultaneously etched. However, the embodiments are not limited thereto. After the first process of forming the end portion ENDGR of the metal layer 230 by etching at least the portion of the metal layer 230, the second process of forming the groove GR in the first organic insulating layer 209 by etching at least the portion of the first organic insulating layer 209 may be performed.

Referring to FIGS. 11 to 13 and 14B, the metal layer 230 may be formed on the first organic insulating layer 209. More particularly, the metal layer 230 may be on the first organic insulating layer 209 and the fourth insulating layer 207. As described above, the metal layer 230 may be formed as a multi-layer including Ti/Al/Ti.

In an embodiment, the end portions ENDGR may be formed in the metal layer 230 as a portion of the metal layer 230 may be etched. In detail, as the portion of the metal layer 230 on the first organic insulating layer 209 filling the holes H(IIL) of the inorganic insulating layer IIL may be etched, the end portions ENDGR may be formed in the metal layer 230.

In order that the portion of the metal layer 230 formed on the holes H(IIL) of the inorganic insulating layer may be etched and the end portions ENDGR may be formed in the metal layer 230, a photoresist PR may be formed on the metal layer 230. The photoresist PR disposed on and corresponding to the at least a portion of the metal layer 230 corresponding to the holes H(IIL) of the inorganic insulating layer IIL may be removed. In other words, portions of the photoresist PR which correspond to a portion to be removed from the metal layer 230 may be removed. As a portion of the metal layer 230, from which the photoresist PR has been removed may be removed by etching, the end portions ENDGR may be formed in the metal layer 230. In other words, at least the portion of the metal layer 230 corresponding to the holes H(IIL) of the inorganic insulating layer IIL may be etched, and the end portions ENDGR of the metal layer 230 may be formed. In detail, the at least a portion of the metal layer 230 corresponding to the holes H(IIL) of the inorganic insulating layer IIL may be removed by dry etching. The end portions ENDGR of the metal layer 230 may be apart (i.e., spaced apart) from one another at locations corresponding to the holes H(IIL) of the inorganic insulating layer IIL. As the end portions ENDGR may be formed in the metal layer 230, the functional layers (i.e., the first functional layer 222a and the second functional layer 222c) and the counter electrode 223 extending from the display area DA to the intermediate area MA may be short-circuited at the end portions ENDGR of the metal layer 230. The protective layer 240 may also be short-circuited at the metal layer 230. As the functional layers (i.e., the first functional layer 222a and the second functional layer 222c) and the counter electrode 223 may be short-circuited at the end portions ENDGR of the metal layer 230, permeation of foreign moisture or air into the display area DA through the functional layers (i.e., the first functional layer 222a and the second functional layer 222c) and the counter electrode 223 in the intermediate area MA may be prevented.

As the portion of the metal layer 230 corresponding to the holes H(IIL) of the inorganic insulating layer IIL may be etched and the end portions ENDGR may be formed in the metal layer 230, the at least a portion of the first organic insulating layer 209 under the metal layer 230 may be simultaneously removed, and thus the groove GR may be formed in the first organic insulating layer 209. As the at least a portion of the metal layer 230 undergoes dry etching and the end portions ENDGR may be formed in the metal layer 230, the first organic insulating layer 209 disposed under the metal layer 230 may be etched at a rate higher than a rate at which the metal layer 230 is etched. In detail, in an etching process, in case that a length t1 by which the end portions ENDGR of the metal layer 230 protrude more than the first organic insulating layer 209 in a first direction (e.g., the x direction or −x direction) 0.3 um, a length t2 of the grooves GR in the first organic insulating layer 209 in a direction (e.g., the z direction or −z direction) perpendicular to the substrate 100 may be 0.675 um. In other words, in the etching process, a ratio of the length t1 by which the end portions ENDGR of the metal layer 230 protrude more than the first organic insulating layer 209 in the first direction (e.g., the x direction or −x direction) and the length t2 of the grooves GR in the first organic insulating layer 209 in the direction (e.g., the z direction or −z direction) perpendicular to the substrate 100 may be 1:2.25. However, the disclosure may not be limited thereto.

After the metal layer 230 and the first organic insulating layer 209 have been simultaneously etched and the end portions ENDGR of the metal layer 230 and the grooves GR in the first organic insulating layer 209 have been respectively formed, remaining portions of the photoresist PR may be removed. However, the disclosure is not limited thereto.

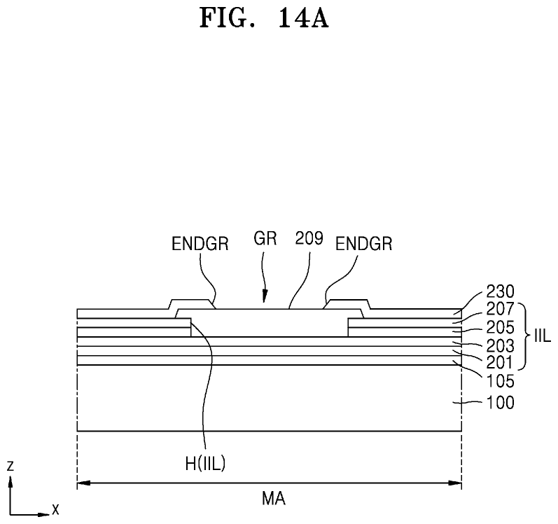

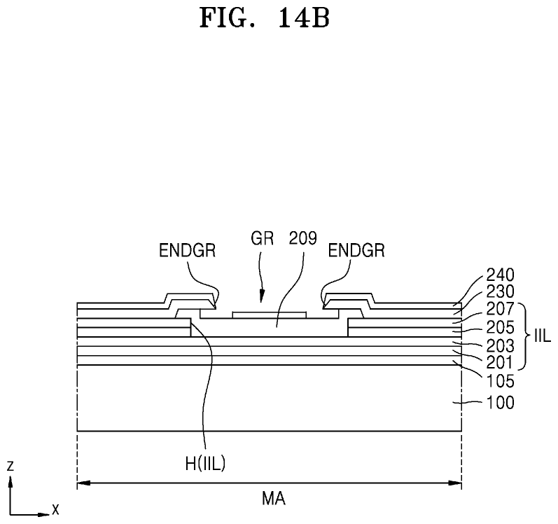

In an embodiment, referring to FIGS. 14A and 14B, a process of forming the end portion ENDGR of the metal layer 230 and the first organic insulating layer 209 may include the first process and the second process. The first process may include the process of forming the end portion ENDGR of the metal layer 230 by etching at least the portion of the metal layer 230 arranged in contact with the top surface of the first organic insulating layer 209. The second process may include the process of forming the groove GR in the first organic insulating layer 209 by etching at least a portion of the first organic insulating layer 209. In time, the second process may be performed after the first process. As different targets (i.e., the metal layer 230 and the first organic insulating layer 209) are respectively removed in the first process and the second process, different types of etchants may be used in the first process and the second process.

The minimum thickness t2 from the bottom surface of the metal layer 230 to the groove GR in the first organic insulating layer 209 may be greater than a length t1 to which the end portion ENDGR of the metal layer 230 protrudes inward from the first organic insulating layer 209 in a direction toward the groove GR in the first organic insulating layer 209. The depth t2 (i.e., the minimum distance from the bottom surface of the metal layer 230 to the groove GR in the first organic insulating layer 209) may include the depth t2 to which the first organic insulating layer 209 is etched in the third direction (e.g., the z direction or the −z direction) in the process of forming the end portion ENDGR of the metal layer 230 by etching at least the portion of the metal layer 230 arranged in contact with the top surface of the first organic insulating layer 209 (or the first process) and the process of forming the groove GR in the first organic insulating layer 209 by etching at least the portion of the first organic insulating layer 209 (or the second process). The length t1 to which the end portion ENDGR of the metal layer 230 protrudes in the direction toward the groove GR in the first organic insulating layer 209 may include the length t1 to which the first organic insulating layer 209 is etched in the first direction (e.g., the x direction or the −x direction) in the process of etching at least the portion of the first organic insulating layer 209 to form the groove GR in the first organic insulating layer 209. While the minimum distance t2 (or the depth of the groove) from the bottom surface of the metal layer 230 to the groove GR in the first organic insulating layer 209 may include the length to which the first organic insulating layer 209 is etched in the third direction (e.g., the z direction or the −z direction) while performing two processes (i.e., the first process and the second process) the length t1 to which the end portion ENDGR of the metal layer 230 protrudes in the direction toward the groove GR in the first organic insulating layer 209 may include the length to which the first organic insulating layer 209 is etched in the first direction (e.g., the x direction or the −x direction) while performing one process (i.e., the second process). Therefore, the minimum distance t2 from the bottom surface of the metal layer 230 to the groove GR in the first organic insulating layer 209 may be greater than the length t1 to which the end portion ENDGR of the metal layer 230 protrudes inward from the first organic insulating layer 209 in the direction toward the groove GR in the first organic insulating layer 209.

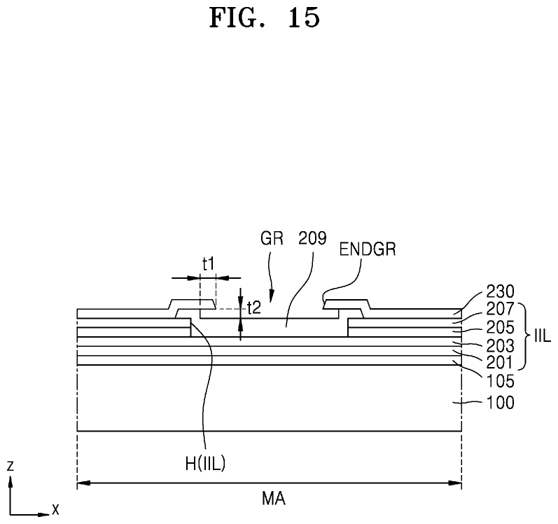

Referring to FIG. 15, the protective layer 240 may be formed on the metal layer 230 and on the first organic insulating layer 209. The protective layer 240 may be simultaneously patterned and formed with the pixel electrode 221 of the organic light-emitting diode OLED disposed in the display area DA, and may include a material that may be the same as a material included in the pixel electrode 221. As described above, the protective layer 240 may include a conductive oxide material such as indium tin oxide (ITO), indium zinc oxide (IZO), zinc oxide (ZnO), indium oxide (In₂O₃), indium gallium oxide (IGO), aluminum zinc oxide (AZO), or a combination thereof. As an embodiment, the protective layer 240 may include a reflective film including Ag. Mg. Al, Pt. Pd, Au, Ni, Nd, Ir. Cr, a compound thereof, or a combination thereof. As an embodiment, the protective layer 240 may further include a film formed of ITO, IZO, ZnO, or In₂O₃, or a combination thereof above/under the aforementioned reflective film.

The protective layer 240 may cover the top surface and side surfaces of the metal layer 230. As the protective layer 240 may be short-circuited by the end portions ENDGR of the metal layer 230, the protective layer 240 may also be disposed at locations corresponding to the grooves GR in the first organic insulating layer 209. As the protective layer 240 covers the top surface and side surfaces of the metal layer 230, the occurrence of defective factors due to a reduction reaction between Al of the metal layer 230 and Ag of the protective layer 240 may be prevented, and the occurrence of defects in subsequent layers due to formation of an undercut structure between Al and Ti of the metal layer 230 as Al of the metal layer 230 is etched by an etchant of another layer in the following process may be prevented.

The holes H(IIL) may be formed in the inorganic insulating layer IIL in the intermediate area MA of the display panel 10, the grooves GR may be formed in the first organic insulating layer 209 filling the holes H(IIL) of the inorganic insulating layer IIL, and the metal layer 230 disposed on the first organic insulating layer 209 may include the end portions ENDGR. By the end portions ENDGR of the metal layer 230 disposed in the intermediate area MA of the display panel 10 and the grooves GR in the first organic insulating layer 209, the functional layers (i.e., the first functional layer 222a and the second functional layer 222c) and the counter electrode 223 extending from the display panel 10 to the intermediate area MA may be short-circuited. By having the functional layers (i.e., the first functional layer 222a and the second functional layer 222c) and the counter electrode 223 short-circuited in the intermediate area MA, permeation of foreign air or moisture into the display area DA through the functional layers (i.e., the first functional layer 222a and the second functional layer 222c) and the counter electrode 223 may be prevented.

In a process of forming the end portions ENDGR of the metal layer 230 by etching the metal layer 230 disposed on the first organic insulating layer 209, at least a portion of the first organic insulating layer 209 may be simultaneously etched, and thus, the grooves GR may be formed. As the end portions ENDGR of the metal layer 230 and the grooves GR in the first organic insulating layer 209 may be formed without using additional masks, time spent for the process of manufacturing the display panel 10 may be reduced, and the efficiency in the manufacturing process may be improved as much as possible.

The protective layer 240 may be formed on the metal layer 230, and the protective layer 240 may cover the top surfaces and side surfaces of the end portions ENDGR of the metal layer 230. As the protective layer 240 covers the side surfaces of the metal layer 230, the occurrence of defective factors due to a reduction reaction between Al of the metal layer 230 and Ag of the protective layer 240 may be prevented, and the occurrence of defects in subsequent layers due to formation of an undercut structure between Al and Ti of the metal layer 230 may be prevented.

The display device regarding the embodiments of the disclosure may prevent foreign impurities such as moisture from causing damage to the display elements, with reference to the opening area. However, this is merely an example, and effects according to the embodiments will be described in detail in the following descriptions.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
an opening area, a display area surrounding at least a portion of the opening area, and an intermediate area disposed between the opening area and the display area;
an inorganic insulating layer disposed on a substrate and including a plurality of holes;
a first organic insulating layer filling the plurality of holes and having a plurality of grooves disposed in a top surface;
a metal layer disposed on the first organic insulating layer and comprising a plurality of end portions; and
a protective layer disposed on the metal layer, wherein
each of the plurality of end portions of the metal layer is spaced apart from one another above the plurality of grooves, and
top surfaces and side surfaces of each of the plurality of end portions of the metal layer are covered by the protective layer.

2. The display device of claim 1, wherein the protective layer is also disposed in the plurality of grooves disposed in the first organic insulating layer.

3. The display device of claim 1, further comprising:
a first dam disposed in the intermediate area.

4. The display device of claim 3, wherein
at least one of the plurality of holes defined in the inorganic insulating layer is disposed between the display area and the first dam, and
the first organic insulating layer filling the at least one of the plurality of holes disposed between the display area and the first dam comprises at least one of the plurality of grooves disposed on the top surface.

5. The display device of claim 3, further comprising:
a second dam disposed between the first dam and the opening area.

6. The display device of claim 5, wherein
at least one of the plurality of holes defined in the inorganic insulating layer is disposed between the first dam and the second dam, and
the first organic insulating layer filling the at least one of the plurality of holes disposed between the first dam and the second dam comprises at least one of the plurality of grooves disposed on the top surface.

7. The display device of claim 1, further comprising:
a second organic insulating layer disposed on the first organic insulating layer.

8. The display device of claim 5, wherein each of the first dam and the second dam comprise:
a second organic insulating layer; and
a third organic insulating layer disposed on the second organic insulating layer.

9. The display device of claim 5, wherein
at least one of the plurality of holes defined in the inorganic insulating layer is disposed between the second dam and the opening area, and
the first organic insulating layer filling the at least one of the plurality of holes disposed between the second dam and the opening area comprises at least one of the plurality of grooves disposed on the top surface thereof.

10. The display device of claim 1, further comprising:
a light-emitting device comprising a pixel electrode and a counter electrode disposed in the display area and a functional layer disposed between the pixel electrode and the counter electrode,
wherein the protective layer and the pixel electrode comprise a same material.

11. The display device of claim 7, wherein in a portion of the intermediate area adjacent to the display area, the protective layer covers a top surface of a peripheral end of the metal layer contacting the second organic insulating layer.

12. The display device of claim 8, wherein the third organic insulating layer included in the first dam covers the metal layer and the protective layer contacting the second organic insulating layer included in the first dam.

13. The display device of claim 8, wherein the third organic insulating layer included in the second dam covers the metal layer and the protective layer contacting the second organic insulating layer included in the second dam.

14. A method of manufacturing a display device, the method comprising:
forming an inorganic insulating layer on a substrate, the display device comprising an opening area, a display area surrounding at least a portion of the opening area, and an intermediate area disposed between the opening area and the display area;
forming a plurality of holes by removing at least a portion of the inorganic insulating layer disposed in the intermediate area;
forming a first organic insulating layer in the plurality of holes of the inorganic insulating layer;
forming a metal layer on the first organic insulating layer;
forming a plurality of end portions in the metal layer by etching at least a portion of the metal layer corresponding to the plurality of holes; and
forming a protective layer on the metal layer, wherein the protective layer covers top surfaces and side surfaces of each of the plurality of end portions of the metal layer.

15. The method of claim 14, wherein in the forming of the plurality of end portions of the metal layer by etching the at least a portion of the metal layer corresponding to the plurality of holes, at least a portion of the first organic insulating layer is simultaneously etched to produce a plurality of grooves disposed in the first organic insulating layer.

16. The method of claim 15, wherein the protective layer is also formed at a location corresponding to the plurality of grooves in the first organic insulating layer.

17. The method of claim 15, wherein ones of the plurality of end portions of the metal layer are spaced apart from one another and are disposed at a location corresponding to the plurality of grooves.

18. The method of claim 14, wherein the forming of the plurality of end portions in the metal layer by etching the at least a portion of the metal layer corresponding to the plurality of holes comprises:
arranging a photoresist on the metal layer;
patterning the photoresist by removing a portion of the photoresist corresponding to the at least a portion of the metal layer corresponding to the plurality of holes;
etching and removing the at least a portion of the metal layer corresponding to the plurality of holes; and
removing the patterned photoresist.

19. The method of claim 14, wherein the protective layer is simultaneously formed with a pixel electrode of a light-emitting device disposed in the display area.

20. The method of claim 19, wherein the protective layer and the pixel electrode comprise a same material.
